(19) United States
(12) Patent Application Publication
(10) Pub. No.: US 2026/0101637 A1
(43) Pub. Date: Apr. 9, 2026

(54) DISPLAY DEVICE AND METHOD OF MANUFACTURING THE SAME

(71) Applicant: Samsung Display Co., LTD., Yongin-si (KR)

(72) Inventors: SUNGJOON KWAK, Yongin-si (KR); JONGHYEON KANG, Yongin-si (KR); Byeongwan Kim, Yongin-si (KR); JEMIN LEE, Yongin-si (KR)

(73) Assignee: Samsung Display Co., LTD., Yongin-si (KR)

(21) Appl. No.: 19/194,558

(22) Filed: Apr. 30, 2025

(30) Foreign Application Priority Data
Oct. 7, 2024 (KR) 10-2024-0136031

(51) Int. Cl. H10K 59/121; H10K 59/12

(52) U.S. Cl. CPC H10K 59/1216; H10K 59/1201; H10K 59/1213

(57) ABSTRACT

A display device includes a thin film transistor positioned on a substrate and including a driving transistor, a capacitor electrically connected to the driving transistor, a light-emitting element electrically connected to the driving transistor, and a base metal layer respectively positioned between the substrate and the driving transistor and between the substrate and the capacitor. The base metal layer includes a first layer and a second layer sequentially laminated on the substrate, an end of the second layer is recessed inward from an end of the first layer and positioned on an upper surface of the first layer, and a protective layer including atoms of the first layer is positioned on a side surface of the first layer.

### CROSS-REFERENCE TO RELATED APPLICATION(S)

This application claims priority to and benefits of Korean Patent Application No. 10-2024-0136031 under 35 U.S.C. § 119, filed on Oct. 7, 2024, in the Korean Intellectual Property Office (KIPO), the entire contents of which are incorporated herein by reference.

### BACKGROUND

### 1. Technical Field

The disclosure relates to a display device and a method of manufacturing the same.

### 2. Description of the Related Art

As demand for display devices expands, the need for display devices that may be used for various purposes is also increasing. In line with this trend, display devices are becoming increasingly larger and thinner, and the need for display devices that provide larger and thinner display devices while also providing accurate and vivid colors is increasing.

### SUMMARY

Embodiments of the disclosure aim to provide a display device with improved stability and optical properties and a method of manufacturing the same.

However, these tasks are exemplary and the tasks to be solved by the disclosure are not limited thereto.

According to an embodiment of the disclosure, a display device may include a thin film transistor positioned on a substrate and including a driving transistor, a capacitor electrically connected to the driving transistor, a light-emitting element electrically connected to the driving transistor, and a base metal layer respectively positioned between the substrate and the driving transistor and between the substrate and the capacitor. The base metal layer may include a first layer and a second layer sequentially laminated on the substrate, an end of the second layer may be recessed inward from an end of the first layer and positioned on an upper surface of the first layer, and a protective layer including atoms of the first layer may be positioned on a side surface of the first layer.

In an embodiment, the first layer may include aluminum, and the protective layer may include aluminum and fluoride.

In an embodiment, a thickness of the protective layer may be in a range of about 5 nm to about 15 nm.

In an embodiment, a gap between the end of the first layer and the end of the second layer may be greater than 0 and less than 50 μm.

In an embodiment, the second layer may include titanium.

In an embodiment, the base metal layer may further include a third layer positioned between the substrate and the first layer, and the third layer and the second layer may include a same material.

In an embodiment, an end of the third layer may be projected further outward than the end of the first layer, and the protective layer may cover an outer surface of the end of the third layer.

In an embodiment, a side surface of the base metal layer may have a taper angle in a range of about 40° to about 60°.

In an embodiment, the thin film transistor may include an active layer, a gate electrode, a source electrode, and a drain electrode, and at least one of the gate electrode, the source electrode, and the drain electrode and the base metal layer may have a same structure.

In an embodiment, the light-emitting element may include an organic light-emitting element, and the active layer may include an oxide semiconductor.

According to an embodiment of the disclosure, a method of manufacturing a display device may include forming a base metal layer including a first base metal layer and a second base metal layer on a substrate, forming a thin film transistor on the substrate at a position overlapping the first base metal layer and forming a capacitor on the substrate at a position overlapping the second base metal layer in a plan view, and forming a light-emitting element electrically connected to the thin film transistor. The forming of the base metal layer may include a primary etching of sequentially laminating a first layer including aluminum and a second layer including titanium on the substrate and etching the first layer and the second layer, and a secondary etching of selectively etching the second layer. An end of the second layer may be formed to be recessed inward more than an end of the first layer and positioned on an upper surface of the first layer, and a protective layer including aluminum and titanium may be formed on a side surface of the first layer.

In an embodiment, the primary etching may be performed by dry etching using a mixture of chlorine (Cl₂) and boron trichloride (BCl₃).

In an embodiment, the secondary etching may be performed by dry etching using a mixture of carbon tetrafluoride (CF₄) and chlorine (Cl₂).

In an embodiment, a side surface of the base metal layer may have a taper angle in a range of about 40° to about 60°.

In an embodiment, a gap between the end of the first layer and the end of the second layer may be greater than 0 and less than 50 μm.

In an embodiment, a thickness of the protective layer may be in a range of about 5 nm to about 15 nm.

In an embodiment, the forming of the base metal layer may further include forming a third layer including titanium between the first layer and the substrate.

In an embodiment, an end of the third layer may be projected further outward than the end of the first layer, and the protective layer may be formed to cover an outer surface of the end of the third layer.

In an embodiment, the thin film transistor may include an active layer, a gate electrode, a source electrode, and a drain electrode, and at least one of the gate electrode, the source electrode, and the drain electrode and the base metal layer may have a same structure.

According to an embodiment of the disclosure, an electronic device may include a processor that provides image data, a display device that displays an image based on the image data, a memory that stores the image data, and a power module that provides a power to the processor and the display device. The display device may include a thin film transistor positioned on a substrate and including a driving transistor, a capacitor electrically connected to the driving transistor, a light-emitting element electrically connected to the driving transistor, and a base metal layer respectively positioned between the substrate and the driving transistor and between the substrate and the capacitor. The base metal layer may include a first layer and a second layer sequentially laminated on the substrate, an end of the second layer may be recessed inward from an end of the first layer and positioned on an upper surface of the first layer, and a protective layer including atoms of the first layer may be positioned on a side surface of the first layer.

### BRIEF DESCRIPTION OF THE DRAWINGS

FIG. 1 is a plan view schematically illustrating a display device according to an embodiment of the disclosure.

FIG. 2 is a schematic block diagram schematically illustrating a structure of the display device of FIG. 1.

FIG. 3 is a plan view schematically illustrating an embodiment of a (sub)pixel of the display device of FIG. 1.

FIG. 4 is a schematic cross-sectional view taken along line I-I′ of FIG. 3 according to an embodiment.

FIG. 5 is a schematic diagram of an equivalent circuit of a (sub)pixel of FIG. 3 according to an embodiment.

FIG. 6 is an enlarged view of part A of FIG. 4.

FIG. 7 is a schematic cross-sectional view schematically illustrating a manufacturing process of the first base metal layer of FIG. 6.

FIG. 8 is an enlarged view of part A of FIG. 4 according to an embodiment.

FIG. 9 is a schematic block diagram of an electronic device according to an embodiment.

FIG. 10 illustrates schematic views of electronic devices according to various embodiments.

### DETAILED DESCRIPTION OF THE EMBODIMENTS

The disclosure may be modified in various ways and has various embodiments. Embodiments are illustrated in the drawings and described in detail in the detailed description. The effects and features of the disclosure and the method for achieving them will become clear with reference to the embodiments described in detail below together with the drawings. However, the disclosure is not limited to the embodiments disclosed below and may be implemented in various forms.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The term “about” may include variations of, for example, ±20%, ±10%, or ±5%, from the specified numerical value unless otherwise expressly stated. In some contexts, the term may account for rounding, inherent measurement limitations, or standard tolerances recognized in the relevant technical field. When applied to dimensions, concentrations, or other quantifiable parameters, “about” may include minor deviations that would be understood by a person of ordinary skill in the art as insubstantial in the given context. The scope of “about” should be interpreted in view of standard experimental or clinical tolerances applicable to the field of use. A person skilled in the art would recognize that “about” allows for practical deviations that do not materially alter the intended properties of the invention. Similarly, for mechanical dimensions, “about” may include deviations that are within industry-accepted tolerances and do not materially impact the performance of the disclosure.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments of the disclosure will be described in detail with reference to the attached drawings. When describing with reference to the drawings, identical or corresponding components are given the same drawing reference numerals and redundant descriptions thereof will be omitted.

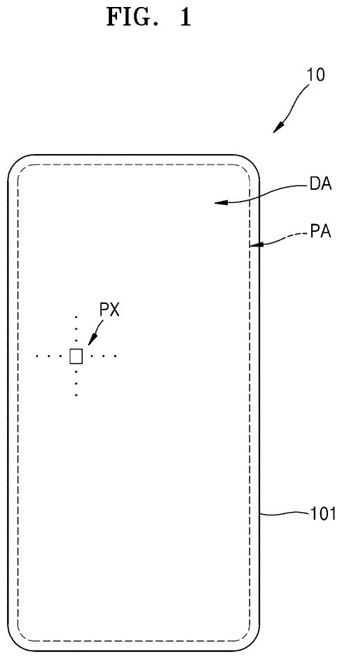

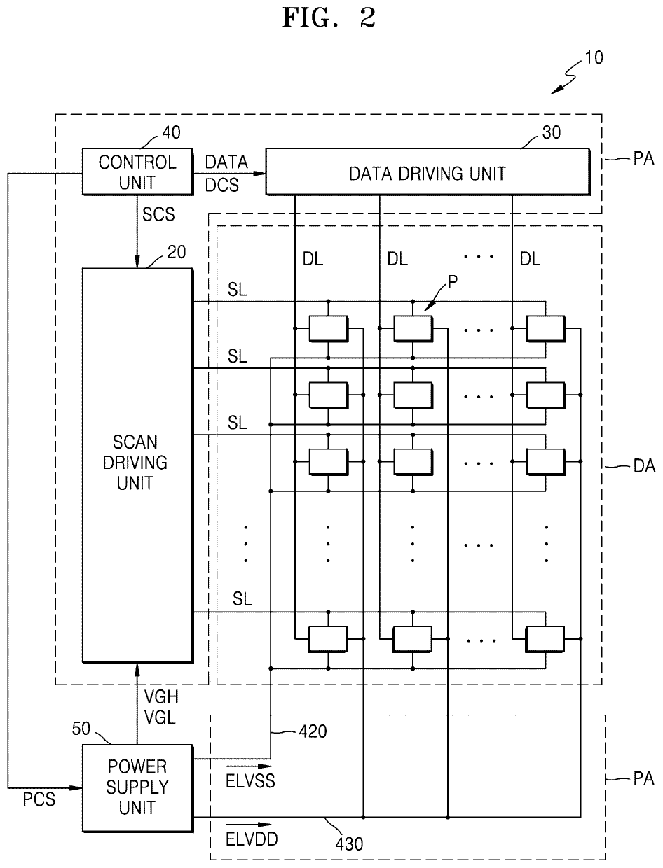

FIG. 1 is a plan view schematically illustrating a display device according to an embodiment of the disclosure, and FIG. 2 is a schematic block diagram schematically illustrating a structure of the display device of FIG. 1.

Referring to FIGS. 1 and 2, a display device 10 according to an embodiment of the disclosure may include a display area DA that displays an image and a peripheral area PA located outside the display area DA.

In the display area DA, multiple scan lines SL extending in a first direction, multiple data lines DL extending in a second direction intersecting the first direction, and multiple (sub)pixels PX may be positioned.

Each of the (sub)pixels PX may be connected to a corresponding data line DL among the data lines DL and a corresponding scan line SL among the scan lines SL and may receive a data signal and a scan signal.

Each (sub)pixel PX may include a light-emitting element and emit red, green, blue, or white light. For example, each (sub)pixel PX may include an organic light emitting diode OLED as a light-emitting element.

A scan driving unit 20, a data driving unit 30, a control unit 40, a common voltage line 420, a driving voltage line 430, or the like may be disposed in the peripheral area PA.

The scan driving unit 20 may receive a scan driving unit control signal SCS from the control unit 40 and generate a scan signal in response thereto.

The data driving unit 30 may receive image data DATA and a data driving unit control signal DCS from the control unit 40, generate a data signal in response thereto, and supply the generated data signal to data lines DL.

The control unit 40 may control the scan driving unit 20, the data driving unit 30, and a power supply unit 50. The control unit 40 may generate a scan driving unit control signal SCS, a data driving unit control signal DCS, and a power supply control signal PCS based on a control signal from an external source, thereby controlling the scan driving unit 20, the data driving unit 30, and the power supply unit 50.

The power supply unit 50 may supply a common voltage ELVSS and a driving voltage ELVDD to each pixel PX through the common voltage line 420 and the driving voltage line 430. In an embodiment, the driving voltage ELVDD may be a positive voltage, and the common voltage ELVSS can be a negative voltage or ground voltage. In an embodiment, the power supply unit 50 may supply a first driving voltage VGH and a second driving voltage VGL to the scan driving unit 20.

The first driving voltage VGH and the second driving voltage VGL may be different voltages. In an embodiment, the first driving voltage VGH may be a positive voltage higher than the driving voltage ELVDD, and the second driving voltage VGL may be a negative voltage lower than the common voltage ELVSS.

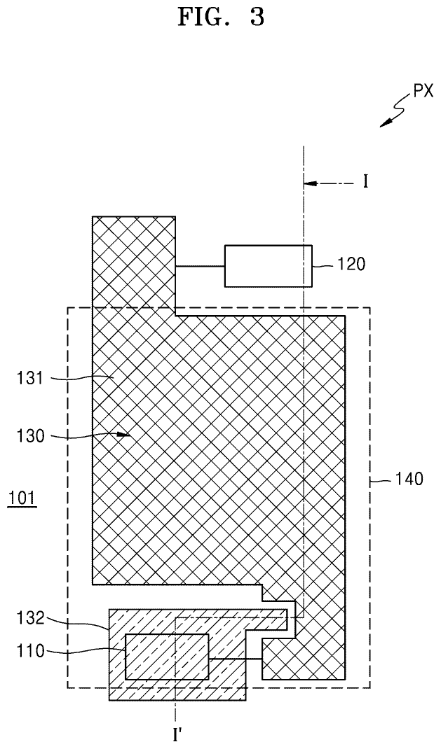

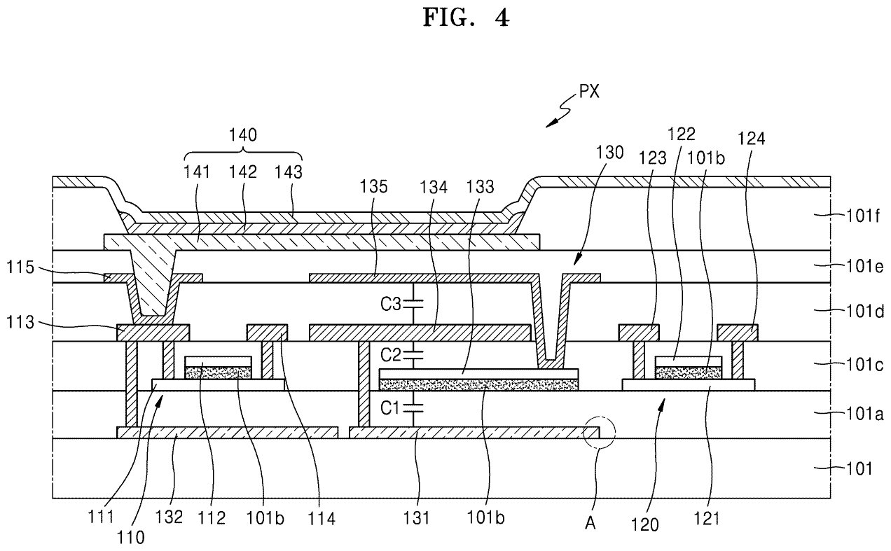

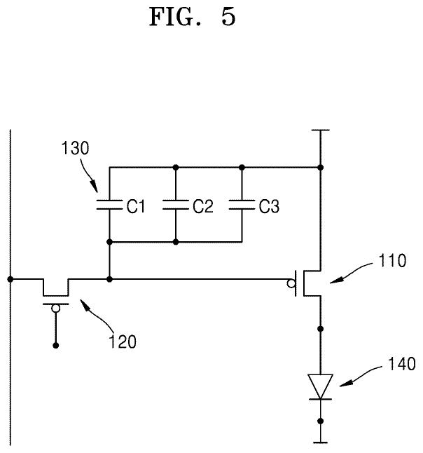

FIG. 3 is a plan view schematically illustrating an embodiment of a (sub)pixel of the display device of FIG. 1, FIG. 4 is a schematic cross-sectional view taken along line I-I′ of FIG. 3 according to an embodiment, and FIG. 5 is a schematic diagram of an equivalent circuit of a (sub)pixel of FIG. 3 according to an embodiment.

Referring to FIGS. 3 to 5, a (sub)pixel PX may include thin film transistors 110 and 120 and a light-emitting element 140 electrically connected to the thin film transistors 110 and 120. A (sub)pixel PX may include a capacitor 130 that applies a gate signal to the driving transistor 110 among the thin film transistors 110 and 120.

The thin film transistors 110 and 120 may include a driving transistor 110, a switching transistor 120, or the like. In an embodiment, base metal layers 131 and 132 that block light may be positioned at least below the driving transistor 110 among the capacitor 130 and the thin film transistors 110 and 120. The base metal layers 131 and 132 may have a laminated structure of at least a first layer and a second layer including different materials. The first layer may include Al, and the second layer may include Ti.

In an embodiment, a first base metal layer 131 may be arranged in the region of the capacitor 130, and a second base metal layer 132 is arranged in the region of the driving transistor 110, so that each of the first base metal layer 131 and the second base metal layer 132 may perform a light-blocking function to prevent light from entering or exiting through a substrate 101. In an embodiment, the first base metal layer 131 may be electrically connected to a second metal layer 134, and the second base metal layer 132 may be electrically connected to a source electrode 113 of the driving transistor 110 to provide electrical properties.

In an embodiment, a driving transistor 110, a switching transistor 120, and a capacitor 130 may be provided on the substrate 101, and a light-emitting element 140 electrically connected to the driving transistor 110 may be positioned thereon.

The substrate 101 may be made of a transparent glass material containing SiO₂ as its main component. However, the disclosure is not necessarily limited thereto. In another embodiment, the substrate 101 may be formed of a transparent plastic material, such as polyethersulfone (PES), polyacrylate (PAR), polyetherimide (PEI), polyethylene napthalate (PEN), polyethylene terephthalate (PET), polyphenylene sulfide (PPS), polyallylate, polyimide, polycarbonate (PC), cellulose triacetate (TAC), cellulose acetate propionate (CAP), or the like.

A buffer layer 101a may be formed on the substrate 101. The buffer layer 101a may include an inorganic material such as silicon oxide, silicon nitride, silicon oxynitride, aluminum oxide, aluminum nitride, titanium oxide, titanium nitride, or the like, or an organic material such as polyimide, polyester, an acrylic material, or the like, and may be formed by multiple laminates of the inorganic material and/or the organic material.

The first base metal layer 131 and the second base metal layer 132 may be formed on the substrate 101 and may be covered by the buffer layer 101a. The first base metal layer 131 and the second base metal layer 132 may be composed of multiple layers to reduce resistance. In an embodiment, the first base metal layer 131 and the second base metal layer 132 may have a first layer including Al and a second layer including Ti on the first layer.

The driving transistor 110 positioned on the buffer layer 101a may include an active layer 111, a gate electrode 112, a source electrode 113, and a drain electrode 114.

The active layer 111 may include, for example, an oxide semiconductor. In an embodiment, the active layer 111 may include an oxide of a material selected from group 12, 13, and 14 metal elements such as zinc (Zn), indium (In), gallium (Ga), tin (Sn), cadmium (Cd), and germanium (Ge), and a combination thereof. For example, the active layer 111 may include G-I-Z-O [(In₂O₃)ₐ(Ga₂O₃)_{b}(ZnO)_{c}] (a, b, and c are real numbers satisfying the conditions of a≥0, b≥0, and c [symbol] 0, respectively).

The gate electrode 112 may be positioned on the active layer 111 with a gate insulation layer 101b interposed between the gate electrode 112 and the active layer 111.

The gate electrode 112 may be formed as a monolayer or multilayer including at least one of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

The gate electrode 112 and the base metal layers 131 and 132 may have a same structure. For example, the gate electrode 112 may be formed of a laminated structure having at least a first layer including Al and a second layer including Ti on the first layer.

The gate insulation layer 101b may be formed as a multilayer or monolayer film made of an inorganic material such as silicon oxide and silicon nitride.

The source electrode 113 and the drain electrode 114 may be formed on the gate electrode 112 with an intermediate insulation layer 101c between the source electrode 113/the drain electrode 114 and the gate electrode 112. The source electrode 113 and the drain electrode 114 may be electrically connected to ends of the active layer 111 doped with N-type or P-type impurities, respectively.

The source electrode 113 and the drain electrode 114 may be formed as a monolayer or multilayer including at least one of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

In an embodiment, at least one of the source electrode 113 and the drain electrode 114 and the base metal layers 131 and 132 may have a same structure. For example, at least one of the source electrode 113 and the drain electrode 114 may be formed of a laminated structure having a first layer including at least Al and a second layer including Ti on the first layer.

The intermediate insulation layer 101c may be formed as a multilayer or monolayer film made of an inorganic material. For example, the intermediate insulation layer 101c may include a metal oxide or a metal nitride. In an embodiment, the intermediate insulation layer 101c may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZrO₂), or the like.

A passivation layer 101d may be positioned on the source electrode 113 and the drain electrode 114. The passivation layer 101d may include an organic insulator such as an acrylic material, benzocyclobutene (BCB), hexamethyldisiloxane (HMDSO), or the like.

A light-emitting element 140 including a pixel electrode 141, a counter electrode 143, and an intermediate layer 142 interposed between the pixel electrode 141 and the counter electrode 143 may be positioned on the passivation layer 101d. The light-emitting element 140 may be an organic light-emitting element.

The pixel electrode 141 may be electrically connected to the source electrode 113 of the driving transistor 110 through, for example, a contact layer 115. In an embodiment, the contact layer 115 may be positioned on the passivation layer 101d, and a planarization layer 101e may be formed on the contact layer 115. The passivation layer 101d may have an opening that exposes, for example, the source electrode 113 of the driving transistor 110, and the contact layer 115 may make contact with the source electrode 113 through this opening.

The planarization layer 101e may include an organic insulator such as an acrylic material, BCB, HMDSO, or the like and may play a role in planarizing the curvature caused by the lower layers.

The pixel electrode 141 may be positioned on the planarization layer 101e and may be electrically connected to the contact layer 115 disposed under the pixel electrode 141 through a via hole.

The pixel electrode 141 may be a (semi)transparent electrode or a reflective electrode. In case that the pixel electrode 141 is a (semi)transparent electrode, the pixel electrode 141 may include, for example, ITO, IZO, ZnO, In₂O₃, IGO, or AZO. In case that the pixel electrode 141 is a reflective electrode, the pixel electrode 141 may have a reflective film formed at least one of Ag, Mg, Al, Pt, Pd, Au, Ni, Nd, Ir, Cr, and a compound thereof, and a layer formed of ITO, IZO, ZnO, In₂O₃, IGO, or AZO. However, the disclosure is not limited thereto, and the pixel electrode 141 may include various materials, and its structure may be modified in various ways, such as being a monolayer or multilayer.

A pixel definition film 101f may be disposed above the planarization layer 101e. The pixel definition film 101f may have an opening that exposes at least a central of the pixel electrode 141, thereby defining a pixel. As shown in FIG. 4, the pixel definition film 101f may prevent arcs or the like from occurring at the edge of the pixel electrode 141 by increasing the distance between the edge of the pixel electrode 141 and the counter electrode 143 above the pixel electrode 141. The pixel definition film 101f may include an organic insulator such as polyimide, HMDSO, or the like.

The intermediate layer 142 of the light-emitting element 140 may include a light-emitting layer. The light-emitting layer may include a polymer or small molecular organic material that emits light of a color. The intermediate layer 142 may include at least one functional layer such as a hole transport layer (HTL), a hole injection layer (HIL), an electron transport layer (ETL), and an electron injection layer (EIL). Such functional layers may include an organic material. In an embodiment, some of the layers forming the intermediate layer 142, for example, functional layer(s), may be formed integrally across multiple light-emitting elements 140.

The counter electrode 143 may cover a display area DA. The counter electrode 143 may be formed integrally with multiple light-emitting elements 140 and correspond to multiple pixel electrodes 141. The counter electrode 143 may be a (semi)transparent electrode or reflective electrode.

In case that the counter electrode 143 is a (semi)transparent electrode, the counter electrode 143 may have a layer formed of a metal having a small work function, i.e. Li, Ca, LiF/Ca, LiF/Al, Al, Ag, Mg, and a compound thereof, and a (semi)transparent conductive layer such as ITO, IZO, ZnO, In₂O₃, or the like. In case that the counter electrode 143 is a reflective electrode, the counter electrode 143 may have a layer formed of Li, Ca, LiF/Ca, LiF/Al, Al, Ag, Mg, and a compound thereof. However, the composition and material of the counter electrode 143 are not limited thereto, and various modifications are possible.

Although not shown in the drawing, an encapsulation layer (not shown) may be disposed above the counter electrode 143. The encapsulation layer (not shown) may serve to protect the light-emitting element 140 from moisture or oxygen from the outside. To this end, the encapsulation layer (not shown) may have a shape that extends not only to the display area DA where the light-emitting element 140 is located, but also to a peripheral area PA outside the display area DA. The encapsulation layer (not shown) may have a multilayer structure. In an embodiment, the encapsulation layer (not shown) may include a first inorganic encapsulation layer, an organic encapsulation layer, and a second inorganic encapsulation layer, which are sequentially laminated.

The first inorganic encapsulation layer may include silicon oxide, silicon nitride, silicon oxynitride, and/or the like. Since the first inorganic encapsulation layer is formed along the structure below it, an upper surface of the first inorganic encapsulation may not be flat.

The organic encapsulation layer may cover the first inorganic encapsulation layer and have a sufficient thickness so that the upper surface of the organic encapsulation layer may be substantially flat over the entire display area DA. The organic encapsulation layer may include polyethylene terephthalate, polyethylene naphthalate, polycarbonate, polyimide, polyethylene sulfonate, polyoxymethylene, polyarylate, hexamethyldisiloxane, an acrylic resin (e.g. polymethyl methacrylate, polyacrylic acid, or the like), or a combination thereof.

The second inorganic encapsulation layer may cover the organic encapsulation layer and may include silicon oxide, silicon nitride and/or silicon oxynitride, or the like. The second inorganic encapsulation layer may be extended outside the organic encapsulation layer and be in contact with the first inorganic encapsulation layer, thereby preventing the organic encapsulation layer from being exposed.

A switching transistor 120 may include an active layer 121, a gate electrode 122, a source electrode 123, and a drain electrode 124. The switching transistor 120 and the driving transistor 110 may be formed with a same laminated structure. However, the disclosure is not limited thereto, and the switching transistor 120 and the driving transistor 110 may include different laminated structures or different materials. In an embodiment, the active layer 121 of the switching transistor 120 may include a semiconductor material such as amorphous silicon, polycrystalline silicon, or the like. In another embodiment, the active layer 121 may include an organic semiconductor material, or the like.

In an embodiment, the second base metal layer 132 may be positioned below the driving transistor 110 close to the light-emitting element 140. The second base metal layer 132 may perform a light-blocking function that blocks light from entering or exiting through the substrate 101, and at the same time, may be connected to the source electrode 113 to stabilize the saturation properties of the source electrode 113 and the drain electrode 114.

The capacitor 130 may include a first capacitor C1, a second capacitor C2, and a third capacitor C3.

The first capacitor C1 may be formed of the first base metal layer 131 and a first metal layer 133 that overlap each other in a plan view with the buffer layer 101a interposed between the first base metal layer 131 and the first metal layer 133. The first metal layer 133 and the gate electrode 112 may be formed of a same material in a same layer.

The second capacitor C2 may be formed of the first metal layer 133 and the second metal layer 134 that overlap each other in a plan view with the intermediate insulation layer 101c interposed between the first metal layer 133 and the second metal layer 134. The second metal layer 134, the source electrode 113, and the drain electrode 114 may be formed of a same material in a same layer.

The third capacitor C3 may be formed of the second metal layer 134 and a third metal layer 135 that overlap each other in a plan view with the passivation layer 101d interposed between the second metal layer 134 and a third metal layer 135. The third metal layer 135 and the contact layer 115 may be formed of a same material in a same layer.

The capacity of the capacitor 130 may be increased by forming three capacitors C1, C2, and C3 in multilayers in a same space in a plan view.

As shown in FIG. 5, the three capacitors C1, C2, and C3 may be connected in parallel and provide a stable voltage to the driving transistor 110. For example, the capacity of the capacitor 130 may be increased by forming three capacitors C1, C2, and C3 in multilayers without increasing a space occupancy, and the stability of the display device 10 may be improved.

The display device 10 may be manufactured by sequentially forming the elements described above. For example, a manufacturing method may include forming base metal layers 131 and 132 including a first base metal layer 131 and a second base metal layer 132 on a substrate 101, forming a capacitor 130 on the substrate 101 at a position overlapping the first base metal layer 131 in a plan view and forming a thin film transistor on the substrate 101 at a position overlapping the second base metal layer 132 in a plan view, and forming a light-emitting element 140 electrically connected to the thin film transistor. In this regard, the thin film transistor may include a driving transistor 110. Below, a method of manufacturing the base metal layers 131 and 132 will be described in detail.

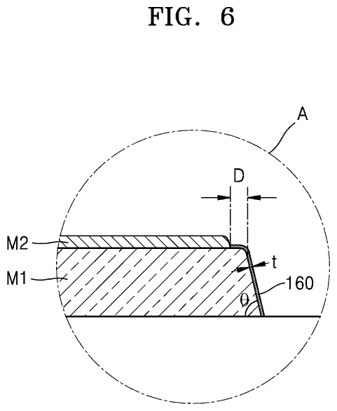

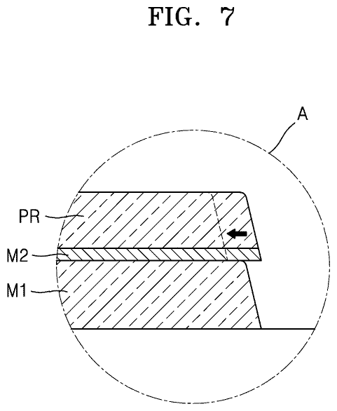

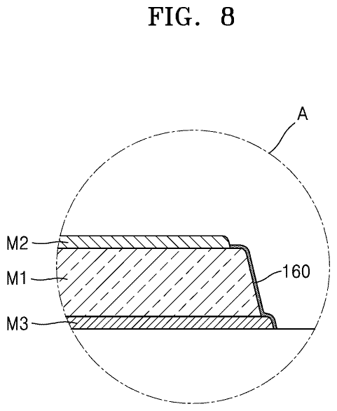

FIG. 6 is an enlarged view of part A of FIG. 4, FIG. 7 is a schematic cross-sectional view schematically illustrating a manufacturing process of the base metal layer of FIG. 6, and FIG. 8 is an enlarged view of part A of FIG. 4 according to an embodiment.

First, referring to FIGS. 6 and 7, a base metal layer may have a laminated structure of at least a first layer M1 and a second layer M2 of different materials. In this regard, the base metal layer may include both the first base metal layer 131 of FIG. 4 and the second base metal layer 132 of FIG. 4 described above.

The first layer M1 may include aluminum. The first layer M1 may act as a main conductive layer and may have a thickness in a range of about 1,000 Å to about 20,000 Å. The first layer M1 may further include at least one of magnesium, manganese, beryllium, hafnium, niobium, tungsten, vanadium, and a combination thereof.

In case that the first layer M1 include aluminum, compared to the case where copper is included, the change in pattern during the etching process (etch skew) may be readily reduced by using a dry etching process, and a design margin may be secured when manufacturing a display device with high resolution. However, in case that the first layer M1 includes aluminum, a hillock may be formed on the surface of the first layer M1, which may cause a short circuit or increase contact resistance.

The second layer M2 may prevent a hillock from forming on the surface of the first layer M1. The second layer M2 may include titanium. The second layer M2 may have a thickness in a range of about 100 Å to about 300 Å. The second layer M2 may include a titanium alloy, such as a titanium-zinc alloy or the like.

The base metal layer may be formed by laminating a first layer M1 and a second layer M2, followed by primary etching, and secondary etching to make an end of the second layer M2 to be recessed inward relative to an end of the first layer M1 to be positioned on the upper surface of the first layer M1.

A primary etching may be done by dry etching that simultaneously etches the first layer M1 and the second layer M2. In an embodiment, a photoresist PR may be formed on the second layer M2 and a dry etching process using the photoresist PR as a mask may be performed.

A gas used in a primary etching process may include a chlorine-containing compound. In an embodiment, the gas used in the primary etching process may be a mixture of chlorine (Cl₂) and boron trichloride (BCl₃).

In an embodiment, since the etching rate of the first layer M1 including Al is greater than the etching rate of the second layer M2 including Ti, after the primary etching, the end of the second layer M2 may have an undercut structure due to a tip projecting outside the end of the first layer M1, as shown in FIG. 7. In case that an active layer 111 of FIG. 4 is formed on the base metal layer, a crack or short circuit of the active layer 111 of FIG. 4 may occur at the end of the second layer M2.

To prevent this phenomenon, the active layer 111 of FIG. 4 may be formed sufficiently thick, but there may be a risk of properties fluctuations due to changes in the thickness of the active layer 111 of FIG. 4. Accordingly, the disclosure may prevent a crack or short circuit from occurring in the active layer 111 of FIG. 4 by selectively removing the second layer M2 through secondary etching.

In an embodiment, as illustrated in FIG. 7, a portion of the photoresist PR on the second layer M2 may be removed to expose an end region of the second layer M2, and the exposed second layer M2 may be selectively removed by dry etching, so that the end of the second layer M2 may be positioned on the upper surface of the first layer M1 by recessing inward relative to the end of the first layer M1.

The gas used in the secondary etching process to remove a portion of the second layer M2 may include a fluorine-containing compound and a chlorine-containing compound. In an embodiment, the fluorine-containing compound may be carbon tetrafluoride (CF₄), and the chlorine-containing compound may be chlorine (Cl₂). Such etching gas may be provided together with a carrier gas such as helium, argon, or the like.

In an embodiment, the flow ratio of carbon tetrafluoride (CF₄) and chlorine (Cl₂) may be in a range of about 1:9 to about 3:7. In case that chlorine (Cl₂) is excessive, a taper angle may become excessively small, and in case that carbon tetrafluoride (CF₄) is excessive, the upper surface area of the exposed first layer M1 may become excessively large, which may cause defects such as hillocks or the like.

The base metal layer formed by secondary etching may have a tapered shape on the end, and the end of the second layer M2 may be formed on the upper surface of the first layer M1 by being recessed inward more than the end of the first layer M1. The side surface of the end of the base metal layer may have a taper angle θ in a range of about 40° to about 60°, and the gap D between the end of the first layer M1 and the end of the second layer M2 may be greater than 0 μm and less than about 50 μm.

During the secondary etching process, a protective layer 160 including atoms of the first layer M1 may be formed on the side surface of the first layer M1. In an embodiment, a protective layer 160 including Al and F may be formed on the exposed side surface of the first layer M1 by a reaction between Al included in the first layer M1 and F included in the etching gas. In an embodiment, a protective layer 160 may include AlF and may have a thickness t in a range of about 5 nm to about 15 nm.

The protective layer 160 may be formed not only on the side surface of the first layer M1 but also on the upper surface of the first layer M1 exposed by removing the end of the second layer M2, thereby preventing the first layer M1 from being damaged during the subsequent manufacturing process of the display device.

Accordingly, the optical properties of the display device may be improved by lowering the resistance of the base metal layer, and the stability may be improved by preventing damage to the active layer 111 of FIG. 4.

FIG. 8 is a schematic cross-sectional view showing another embodiment of a base metal layer. Referring to FIG. 8, the base metal layer may further include a third layer M3 between the first layer M1 and the substrate 101 of FIG. 4 in addition to the first layer M1 and the second layer M2. The first layer M1 and the second layer M2 may be identical to those illustrated and described in FIGS. 6 and 7.

The third layer M3 and the second layer M2 may include a same material. For example, the third layer M3 may include titanium. The second layer M2 may include a titanium alloy, such as a titanium-zinc alloy or the like.

The third layer M3 may have a thickness in a range of about 50 Å to about 500 Å. The third layer M3 may improve the adhesion between the substrate 101 of FIG. 4 and the first layer M1 and protect the first layer M1.

In case that the base metal layer includes a third layer M3, the primary etching process may be performed in a state where the third layer M3, the first layer M1, and the second layer M2 are laminated. As a result, after the primary etching process, the end of the third layer M3 may project further outward than the end of the first layer M1. After the secondary etching process, the protective layer 160 may be formed to cover the end of the projecting third layer M3.

In an embodiment, the structure of the base metal layer described above may be applied equally to at least one of the gate electrode, the source electrode, and the drain electrode, thereby lowering resistance thereof and improving the optical properties of the display device, and in particular, preventing damage to data wiring or the like above the gate electrode, thereby improving stability. In this regard, the gate electrode, source electrode, and drain electrode may include the gate electrode, source electrode, and drain electrode included in the driving transistor 110 of FIG. 4 and the switching transistor 120 of FIG. 4.

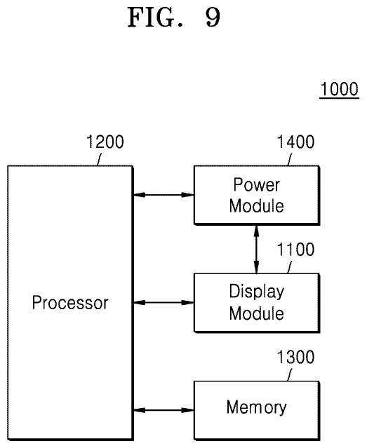

FIG. 9 is a schematic block diagram of an electronic device according to an embodiment. Referring to FIG. 9, an electronic device 1000 according to an embodiment may include a display module 1100, a processor 1200, a memory 1300, and a power module 1400.

The processor 1200 may include at least one of a central processing unit (CPU), an application processor (AP), a graphics processing unit (GPU), a communication processor (CP), an image signal processor (ISP), and a controller.

The memory 1300 may store data information required for operation of the processor 1200 or the display module 1100. An image data signal and/or an input control signal may be transmitted to the display module 1100 in case that the processor 1200 executes an application stored in the memory 1300, and the display module 1100 may output image information through a display screen by processing the received signal.

The power module 1400 may include a power supply module, such as a power adapter or a battery device, and a power conversion module which converts power supplied by the power supply module to generate power required for the operation of the electronic device 1000.

At least one of respective components of the electronic device 1000 may be included in the display device described above. In an embodiment, some of the individual modules functionally included in a module may be included in a display device, while others may be provided separately from the display device. For example, the display device may include the display module 1100, and the processor 1200, the memory 1300, and the power module 1400 may be provided in the form of other apparatuses in the electronic device 1000 other than the display device.

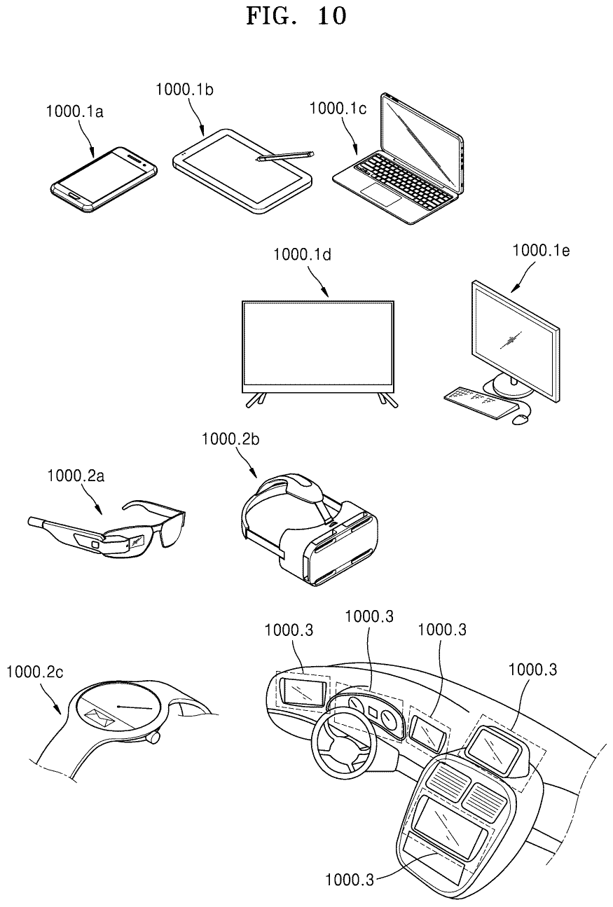

FIG. 10 illustrates schematic views of electronic devices according to various embodiments.

Referring to FIG. 10, various electronic devices according to embodiments, to

which the display device is applied, may include: an electronic device for displaying an image, such as a smart phone 1000.1a, a tablet PC 1000.1b, a laptop computer 1000.1c, a TV set 1000.1d, a desk monitor 1000.1e, and the like; a wearable electronic device including a display module, such as smart glasses 1000.2a, a head mounted display 1000.2b, a smart watch 1000.2c, and the like; and an electronic device 1000.3 for vehicles including a display module, such as a center information display (CID) arranged on an instrument panel, center fascia, or dashboard of a vehicle, a room mirror display, and the like.

According to the disclosure, the stability and optical properties of a display device may be improved.

However, these effects are exemplary, and the effects of the disclosure are not limited thereto.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a thin film transistor positioned on a substrate and including a driving transistor;
a capacitor electrically connected to the driving transistor;
a light-emitting element electrically connected to the driving transistor; and
a base metal layer positioned between the substrate and the driving transistor and between the substrate and the capacitor, wherein
the base metal layer includes a first layer and a second layer sequentially laminated on the substrate,
an end of the second layer is recessed inward from an end of the first layer and is positioned on an upper surface of the first layer, and
a protective layer including atoms of the first layer is positioned on a side surface of the first layer.

2. The display device of claim 1, wherein
the first layer includes aluminum, and
the protective layer includes aluminum and fluoride.

3. The display device of claim 1, wherein a thickness of the protective layer is in a range of about 5 nm to about 15 nm.

4. The display device of claim 1, wherein a gap between the end of the first layer and the end of the second layer is greater than 0 and less than 50 μm.

5. The display device of claim 1, wherein the second layer includes titanium.

6. The display device of claim 1, wherein
the base metal layer further includes a third layer positioned between the substrate and the first layer, and
the third layer and the second layer include a same material.

7. The display device of claim 6, wherein
an end of the third layer is projected further outward than the end of the first layer, and
the protective layer covers an outer surface of the end of the third layer.

8. The display device of claim 1, wherein a side surface of the base metal layer has a taper angle in a range of about 40° to about 60°.

9. The display device of claim 1, wherein
the thin film transistor includes an active layer, a gate electrode, a source electrode, and a drain electrode, and
at least one of the gate electrode, the source electrode, and the drain electrode and the base metal layer have a same structure.

10. The display device of claim 9, wherein
the light-emitting element includes an organic light-emitting element, and
the active layer includes an oxide semiconductor.

11. A method of manufacturing a display device comprising:
forming a base metal layer including a first base metal layer and a second base metal layer on a substrate;
forming a thin film transistor on the substrate at a position overlapping the first base metal layer and forming a capacitor on the substrate at a position overlapping the second base metal layer in a plan view; and
forming a light-emitting element electrically connected to the thin film transistor, wherein
the forming of the base metal layer includes:
a primary etching of sequentially laminating a first layer including aluminum and a second layer including titanium on the substrate and etching the first layer and the second layer; and
a secondary etching of selectively etching the second layer,
an end of the second layer is formed to be recessed inward more than an end of the first layer and positioned on an upper surface of the first layer, and
a protective layer including aluminum and titanium is formed on a side surface of the first layer.

12. The method of claim 11, wherein the primary etching is performed by dry etching using a mixture of chlorine (Cl₂) and boron trichloride (BCl₃).

13. The method of claim 11, wherein the secondary etching is performed by dry etching using a mixture of carbon tetrafluoride (CF₄) and chlorine (Cl₂).

14. The method of claim 11, wherein a side surface of the base metal layer has a taper angle in a range of about 40° to about 60°.

15. The method of claim 11, wherein a gap between the end of the first layer and the end of the second layer is greater than 0 and less than 50 μm.

16. The method of claim 11, wherein a thickness of the protective layer is in a range of about 5 nm to about 15 nm.

17. The method of claim 11, wherein the forming of the base metal layer further includes forming a third layer including titanium between the first layer and the substrate.

18. The method of claim 17, wherein
an end of the third layer is projected outward more than the end of the first layer, and
the protective layer is formed to cover an outer surface of the end of the third layer.

19. The method of claim 11, wherein
the thin film transistor includes an active layer, a gate electrode, a source electrode, and a drain electrode, and
at least one of the gate electrode, the source electrode, and the drain electrode and the base metal layer have a same structure.

20. An electronic device comprising:
a processor that provides image data;
a display device that displays an image based on the image data;
a memory that stores the image data; and
a power module that provides a power to the processor and the display device, wherein
the display device comprises:
a thin film transistor positioned on a substrate and including a driving transistor;
a capacitor electrically connected to the driving transistor;
a light-emitting element electrically connected to the driving transistor; and
a base metal layer positioned between the substrate and the driving transistor and between the substrate and the capacitor,
the base metal layer includes a first layer and a second layer sequentially laminated on the substrate,
an end of the second layer is recessed inward from an end of the first layer and is positioned on an upper surface of the first layer, and
a protective layer including atoms of the first layer is positioned on a side surface of the first layer.
